(19) United States
(12) Patent Application Publication
(10) Pub. No.: US 2008/0038851 A1
(43) Pub. Date: Feb. 14, 2008

(54) Pattern for evaluating electric characteristics, method for evaluating electric characteristics, method for manufacturing semiconductor device and method for providing reliability assurance

(75) Inventors: Shin Koyama, Kanagawa (JP); Mitsuhiro Togo, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/889,267

(22) Filed: Aug. 10, 2007

(30) Foreign Application Priority Data
Aug. 11, 2006 (JP) 2006-219287

(51) Int. Cl. H01L 21/66; G01R 31/26

(52) U.S. Cl. 438/17; 324/769; 257/E21.521

(57) ABSTRACT

An increased area of an element transistor to be evaluated causes an increased leakage current due to a tunnel effect, leading to a reduced accuracy in predicting a TDDB lifetime. A test element group (TEG) 1 is a pattern for evaluating electric characteristics, comprising a plurality of unit transistors T11, T12, T13, T21, T22, T23, T31, T32, T33, which are arranged so as to form a lattice-shaped pattern. Each of the unit transistors comprises a gate dielectric serving as an object to be evaluated, and source region and drain region, which are a short-circuited.

This application is based on Japanese patent application No. 2006-219,287, the content of which is incorporated hereinto by reference.

### BACKGROUND

1. Technical Field

The present invention relates to a pattern for evaluating electric characteristics, a method for evaluating electric characteristics, a method for manufacturing a semiconductor device and a method for providing a reliability assurance.

2. Related Art

The characteristic of TDDB lifetime (time dependent dielectric breakdown) of a gate dielectric is one of factors for representing reliability of semiconductor devices, and is required to be assured at a real operating voltage. Therefore, it is critical to precisely predict such TDDB lifetime, in view of providing semiconductor devices that exhibit an improved reliability. Typical technologies for providing predictions of the TDDB lifetime by employing a pattern for evaluating electric characteristics are disclosed in Japanese Patent Laid-Open No. 2003-31,632, Japanese Patent Laid-Open No. 2002-50,664, Japanese Patent Laid-Open No. H7-66,260 (1995), Japanese Patent Laid-Open No. H9-64,345 (1997) and Mariko Takayanagi et al., entitled “Experimental Study of Gate Voltage Scaling for TDDB under Direct Tunneling Regime”, Reliability Physics Symposium, 2001, Proceedings 39th Annual 2001 IEEE International, 2001, pp. 380-385. For example, in the technology disclosed in Japanese Patent Laid-Open No. 2003-31,632, a metal-oxide-semiconductor (MOS) transistor is employed as an element to be evaluated in a pattern for evaluating electric characteristics.

Here, an expression of “a breakdown of a gate dielectric”, which is often employed in this specification, is not intended to indicate a condition that the gate insulating film is physically destroyed, but is intended to indicate a condition that values of a gate leakage current or the like exhibit lager change than previously expected by applying a constant voltage to the gate electrode (i.e., applying an electric field to the gate insulating film). Such expression is also generally employed in technical documentations.

Now the descriptions will be made in reference to an n-type MOS transistor that utilizes electron as carrier. To turn the MOS transistor into on-state, a positive voltage (for example, 1 Volt) in relation to the substrate is applied to the gate electrode, so that an inversion layer is formed on the semiconductor surface under the gate dielectric. A condition, in which electron is released in the semiconductor surface, is obtained, and then a certain electric field is applied between the source region and the drain region, which is formed in the semiconductor surface so as to be adjacent to the gate, such that carrier, or namely electron, is flowed from the source region to the drain region. To turn the MOS transistor into off-state, a lower voltage (typically 0 Volt) is applied to the gate electrode to obtain a condition, in which carrier is not released in the semiconductor surface under the gate dielectric.

Meanwhile, in view of reducing a measuring time required for predicting the TDDB lifetime, an increased area of the element to be evaluated is preferably employed. This is because larger area of the element to be evaluated provides higher probability of causing a dielectric breakdown. However, larger area of the element to be evaluated also causes an increased leakage current due to a tunnel effect caused therefrom. Then, a problem is occurred, in which an influence of a parasitic resistance is strongly exhibited, causing a reduced accuracy of predicting the TDDB lifetime. In recent years, such problem manifests due to an increased leakage current density, corresponding the reduced film thickness of the gate dielectric.

### SUMMARY

In one embodiment, there is provided a pattern for evaluating electric characteristics of a transistor, comprising a plurality of unit transistors including a gate dielectric and a source and drain region arranged to form a lattice-shaped arrangement, wherein said source and drain region is mutually short-circuited.

A plurality of unit transistors arranged to form a lattice arrangement are provided in such pattern for evaluating electric characteristics. This allows providing a reduced area of each of the unit transistors, while controlling an increase of the time required for the measurement, since the time required mainly depend on the stress applying period. Although the reduced area of each of the unit transistors decreases a probability of occurring a dielectric breakdown in each of the unit transistors, higher probability of detecting a dielectric breakdown can be maintained by measuring characteristics of the entire unit transistors. Therefore, by measuring each unit transistor at a time, this configuration can provide a reduced level of a leakage current generated due to a tunnel effect and flowing through the gate dielectric of respective unit transistors.

In another embodiment, there is provided a method for evaluating electrical characteristics utilizing the pattern for evaluating electric characteristics as set forth above, comprising: applying a first voltage to the gate dielectric of the plurality of unit transistors; measuring a gate current for each of the a plurality of unit transistors when a second voltage is applied to the gate dielectric, after applying the first voltage; determining a magnitude relation between a level of the gate current and a predetermined reference value; and deciding that a breakdown is caused, if the level of the gate current exceeds the reference value according to a result in the determining the magnitude relation.

In the method for evaluating electrical characteristics, the gate current is measured for each of the unit transistors, after the voltage (first voltage) is applied to the gate dielectric s of all unit transistors. Since a leakage current due to the tunnel effect in each of the unit transistors can be reduced as described above (by reducing area of each of the unit transistors and measuring one transistor at a time), such evaluating method allows reducing an influence of a parasitic resistance, thereby providing an improved measurement accuracy.

In another embodiment, there is provided a method for manufacturing a semiconductor device, comprising: forming a plurality of unit transistors so as to be arranged to form a lattice pattern, each of the unit transistors having a gate dielectric; and forming an interconnect so as to short-circuit between a source and drain region of each of the unit transistors.

In the method for manufacturing a semiconductor device, a plurality of unit transistors arranged to form a lattice arrangement is formed, and a short-circuit is created between the source region and the drain region of each of the unit transistors. This allows forming the above-described pattern for evaluating electric characteristics.

In another embodiment, there is provided a method for providing a reliability assurance, comprising: acquiring a breaking time of said gate dielectric in said pattern for evaluating electric characteristics for said different first voltages according to the method for evaluating electrical characteristics as described above; and acquiring a TDDB lifetime of said gate dielectric based on said breaking time obtained for said the first voltages, wherein a reliability assurance of a semiconductor device is provided if said TDDB lifetime is not shorter than a standardized value.

According to the present invention, the pattern for evaluating electric characteristics that is capable of providing a prediction of the TDDB lifetime with higher accuracy in shorter time, the method for evaluating electrical characteristics, the method for manufacturing the semiconductor device and the method for providing the reliability assurance can be achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit schematic, illustrating an embodiment of a pattern for evaluating electric characteristics according to the present invention;

FIG. 2 is a cross-sectional view, illustrating one of the unit transistors shown in FIG. 1;

FIG. 3 is a perspective view, illustrating a condition of an electric coupling for some of the unit transistors shown in FIG. 1;

FIG. 4 is a flow chart, illustrating an embodiment of a method for evaluating electrical characteristics according to the present invention;

FIG. 5 is a graph, which is useful in describing a process for predicting a TDDB lifetime;

FIG. 6 is a graph, which is useful in describing an advantageous effect of an embodiment;

FIG. 7A is a cross-sectional view for describing a structure of a conventional TEG, and FIG. 7B is a cross-sectional view for describing a structure of a TEG according to the embodiment of the present invention; and

FIG. 8A is a plan view for describing a structure of a conventional TEG, and FIG. 8B is a plan view for describing a structure of a TEG according to the embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable exemplary implementations of patterns for evaluating electric characteristics, methods for evaluating electrical characteristics, methods for manufacturing semiconductor devices and methods for providing reliability assurances according to the present invention will be described in reference to the annexed figures. In all figures, identical numeral is assigned to an element commonly appeared in the description of the present invention in reference to the figures, and the detailed description thereof will not be repeated. In the present embodiment, the descriptions will be made in reference to n-type MOS transistors, for the purpose of avoiding descriptive confusions. These descriptions may be also equally applied to p-type MOS transistors, if the signs indicating voltage and electric current are inversed.

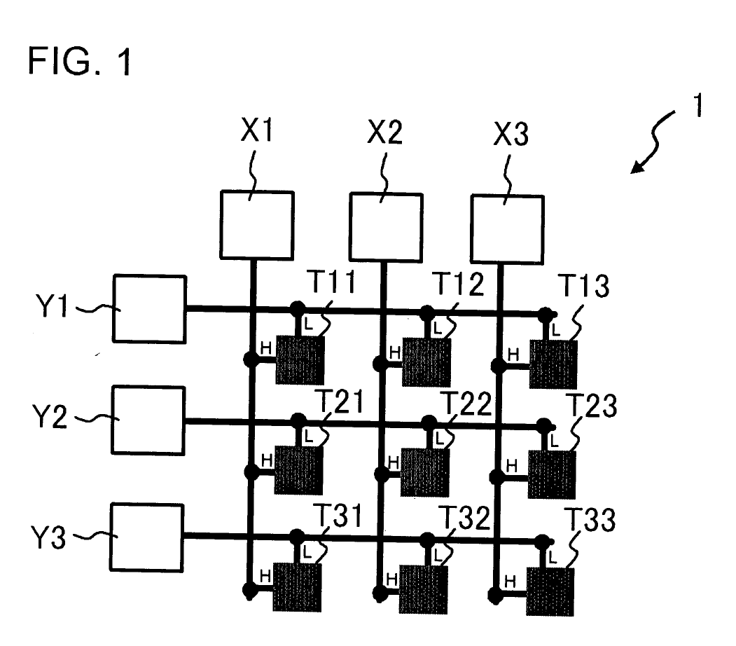

FIG. 1 is a circuit schematic, illustrating an embodiment of a pattern for evaluating electric characteristics according to the present invention. A test element group (TEG) 1 is a pattern for evaluating electric characteristics comprising a plurality of unit transistors T11, T12, T13, T21, T22, T23, T31, T32 and T33, which are arranged to form a lattice pattern or a lattice arrangement.

Each of the unit transistors includes a high (H) terminal and a low (L) terminal. As the description mainly focuses on the n-type MOS transistor, the high (H) terminal serves as a terminal to be applied with a larger positive voltage, and the low (L) terminal serves as a terminal to be applied with a voltage having lower absolute voltage (typically 0 Volt). On the contrary, in the p-type MOS transistor, the high (H) terminal serves as a terminal to be applied with a larger negative voltage. High terminals of the unit transistors T11, T21 and T31 are coupled to a pad X1, high terminals of the unit transistors T12, T22 and T32 are coupled to a pad X2, and high terminals of the unit transistors T13, T23 and T33 are coupled to a pad X3. In addition, low terminals of the unit transistors T11, T12 and T13 are coupled to a pad Y1, low terminals of the unit transistors T21, T22 and T23 are coupled to a pad Y2, and low terminals of the unit transistor T31, T32 and T33 is coupled to a pad Y3.

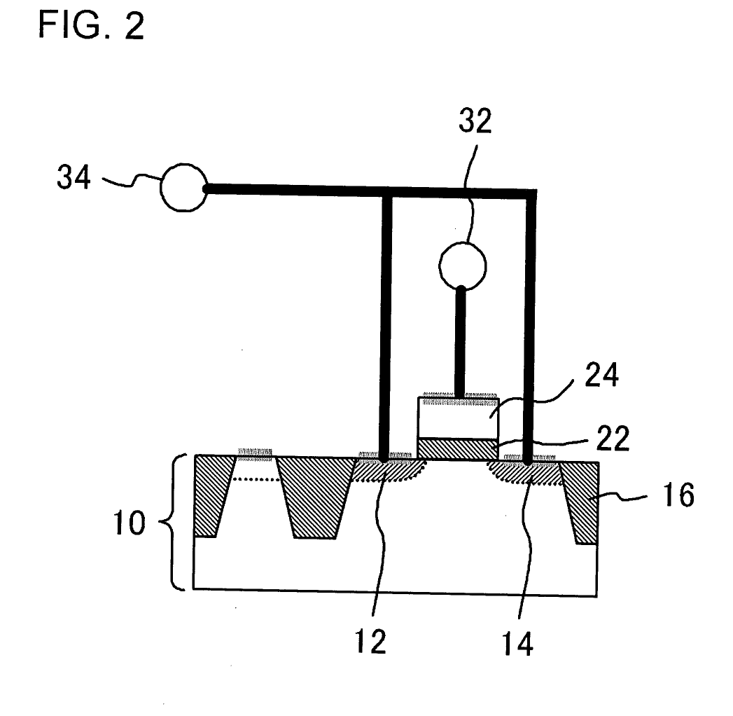

FIG. 2 is a cross-sectional view, which schematically illustrates one of the unit transistors. Each of the unit transistor is a metal-insulator-semiconductor (MIS) transistor, and includes a gate dielectric 22, which is to be evaluated, and a source region 12 and a drain region 14, which are short-circuited. The source region 12 and the drain region 14 are formed in a well region of the semiconductor substrate 10. The source region 12 and the drain region 14 is short-circuited through an interconnect. For the purpose of simplifying the schematic drawing to help the understanding of the configuration, no interlayer film is shown, and an interconnect is represented by a simple line. The semiconductor substrate 10 is, for example, a silicon substrate. A gate electrode 24 composed of a polysilicon is formed on, for example, the gate dielectric 22 Each of the unit transistors is isolated from other unit transistors by element isolation regions 16 such as shallow trench isolation (STI) and the like.

The gate electrode 24 is coupled to a terminal 32, and the source region 12 and the drain region 14, which are short-circuited, is coupled to a terminal 34. When the unit transistor is n-channel type, the terminal 32 and the terminal 34 correspond to the above-described high terminal and low terminal, respectively, and a larger positive voltage is applied to the high terminal. On the other hand, if the unit transistor is p-channel type, a larger negative voltage is applied to the terminal 32 that serves as the high terminal.

It is preferable that each of the unit transistors has the largest area, in sofar as there is no influence of a parasitic resistance. In order to reduce an influence of a parasitic resistance as possible, it is preferable to employ a transistor having a salicide structure. Taking “L” for indicating a gate length of a transistor and “W” for a gate width, an upper limit of L that provides a situation where an influence of a parasitic resistance can be neglected is determined by a channel resistance, and W that provides a situation where an influence of a parasitic resistance can be neglected is determined by a silicide resistance on the gate electrode. Since the channel resistance is about 100 times larger than the silicide resistance in the commonly employed structure, though the level depends on device structures employed, W may be selected to be 100 folds of L, in view of tolerating a level of a parasitic resistance due to the silicide resistance, which is equivalent to a parasitic resistance due to the channel resistance.

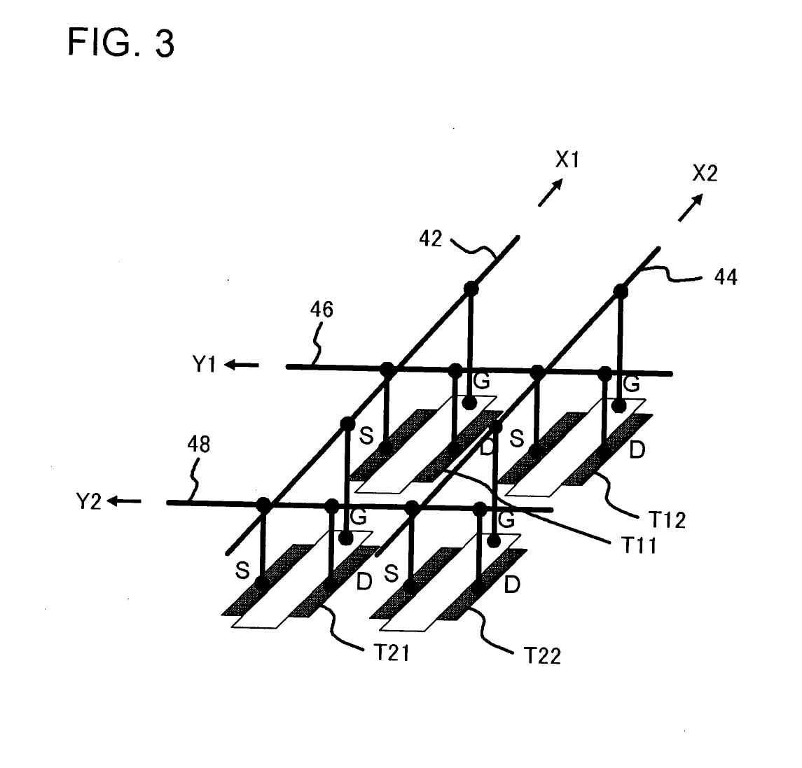

FIG. 3 is a perspective view, which schematically illustrates a condition of electric couplings in some of the unit transistors (T11, T12, T21 and T22) in FIG. 1. Here, a case where each of the unit transistors is n-channel type is illustrated. The gate electrodes (Gs) of the unit transistors T11 and T21 are coupled to a pad X1 through an interconnect 42, and the gate electrodes of the unit transistors T12 and T22, are coupled to a pad X2 through an interconnect 44. The source regions (Ss) and drain region (Ds) of the unit transistors T11 and T12 are coupled to a pad Y1 through an interconnect 46, and the source regions and the drain regions of the unit transistors T21 and T22 are coupled to a pad Y2 through an interconnect 48.

The TEG 1 having such constitution is, for example, formed on a scribe line of a semiconductor wafer in the process for manufacturing the semiconductor device. In the case, the method for manufacturing the semiconductor device comprises forming a plurality of the above-described unit transistors, each of which has a gate dielectric to be evaluated, so as to be arranged to form a lattice pattern; and forming an interconnect so as to create a short-circuit between the source region 12 and the drain region 14 of each of the above-described unit transistors.

The semiconductor device described here may be in a form of a wafer (condition before dicing) or may be in a form of chips (condition after dicing). In the latter case, the unit transistors on the scribe line will disappear in the dicing process. However, it is not essential that the TEG 1 is formed on the scribe line, and a portion or the entire thereof may be formed in a chip region (region to be a chip after dicing). In that case, a portion or the entire of the TEG 1 will remain in the semiconductor device that is in a form of the chip.

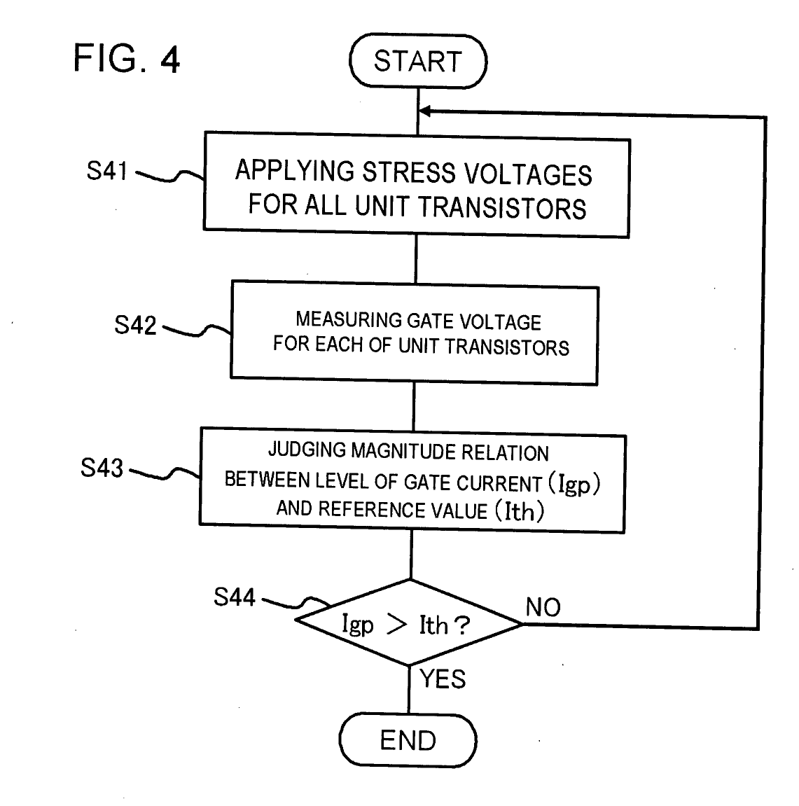

In reference to FIG. 4, an embodiment of a method for evaluating electrical characteristics according to the present invention will be described by illustrating an n-type MOS transistor. In such method for evaluating electrical characteristics, the above-described TEG 1 is employed. First of all, a stress voltage (first voltage) is applied to a gate dielectric of all the unit transistors in the TEG 1 for only a predetermined time. When the reliability corresponding to the operating state of the transistor is evaluated, it is common that a positive larger voltage, namely a voltage considerably larger than the voltage in the operating state, is applied to the gate electrode to create changes in the characteristics change in a shorter time. More specifically, the high potential is applied to pads X1, X2 and X3, and the low potential is applied to pads Y1, Y2 and Y3 (S41). The high potential and the low potential in this case is, for example, 3 Volts and 0 Volt (ground potential), respectively, and thus the above-described stress voltage in this case is to be 3 Volts.

Next, a specified voltage (second voltage) is applied to the gate dielectric of each of the above-described unit transistors, and the gate current in this time is measured (S42). For example, when the gate current of the unit transistors T21 in FIG. 1 is measured, the high potential and the low potential are provided to the pad X1 and the pad Y2, respectively, and other pads X2, X3, Y1 and Y3 are in a condition of open. The high potential and the low potential in this case are, for example, 1 Volt and 0 Volt (i.e., ground potential), respectively, and the above-described specified voltage in this case is to be 1 Volt.

In the steps S41 and S42, it is preferable to apply a stress voltage and a specified voltage so as to form an inversion layer a region under the gate dielectric (in the case of FIG. 2, a region between the source region 12 and the drain region 14 in the surface layers of the semiconductor substrate 10). If the electrical voltages illustrated above (stress voltage: 3 Volts and specified voltage: 1 Volt) are employed, such inversion layer can be formed.

When the stress voltage and the specified voltage are applied in the steps S41 and S42, the potential at the gate electrode is higher than the potentials at the source region and at the drain region, provided that the unit transistor is n-channel type. On the other hand, when the unit transistor is p-channel type, the potential at the gate electrode is lower than the potentials at the source region and at the drain region.

Next, a magnitude relation between the level of the measured gate current (Igp) and the predetermined reference value (Ith) is determined (S43). If the device is n-channel type, a positive voltage is applied to the gate electrode, and a positive electric current flows toward the semiconductor substrate from the gate electrode. If a result of the judgment indicates Igp>Ith for at least one of the unit transistors, it is decided a breakdown is occurred, and then the measurement for the TEG 1 is ended. More specifically, the above-described reference value is taken as a threshold, and it is judged that a dielectric breakdown is occurred if the gate current exceeds the threshold, and on the other hand it is judged that no dielectric breakdown is occurred if the gate current is equal to or lower than the threshold. On the contrary, if results of the judgment indicate Igp<Ith for all unit transistors, the process is returned to the step S41 (S44). More specifically, the steps S41 to S44 are repeatedly implemented until it is decided that a breakdown is occurred in the step S44.

In addition to above, it is not necessary to employ the same value of the above-described reference value for the plurality of unit transistors, and different reference values may also be employed. In such case, manufacturing variations among the unit transistors can be reflected, and optimum reference values can be suitably selected for respective unit transistors. For example, a suitable approach may be that electrical characteristics of respective the unit transistors are measured in advance, and then time taken for detecting a predetermined change from the measured value of the electrical characteristic (e.g., increasing quantity or increasing rate of gate leakage current) is determined as a breaking time.

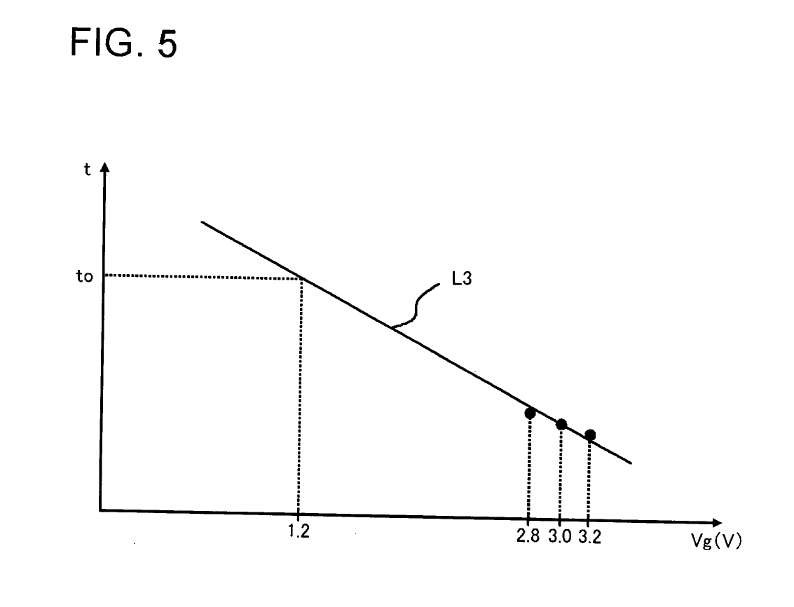

The breaking time for the TEG 1 (i.e., total of time for applying the stress voltage until a dielectric breakdown is occurred) is measured by the procedure described above. When the TDDB lifetime is to be predicted, a plurality of TEGs 1 are prepared, and a breaking time, which is determined to be a time taken for occurring a dielectric breakdown in predetermined number of TEGs 1, is obtained. For example, a breaking time, which is determined to be a time taken for occurring a dielectric breakdown in equal to or larger than fifteen TEGs 1 (equal to or larger than 50% of total number of TEGs 1), is obtained by using thirty TEG 1. The breaking times for different stress voltages are obtained, and the results are plotted as shown in FIG. 5.

Abscissa of the graph of FIG. 5 represents stress voltage Vg, and ordinate represents breaking time t. In this example, the breaking times under the conditions of Vg=2.8V, 3.0V and 3.2 are plotted for the case of employing a silicon dioxide (SiO2) film having a thickness 1.4 nm as the gate dielectric. A straight line (or curved line) L3 is drawn on the basis of these plots, so that a breaking time t0 obtained at the actual operating voltage (1.2 Volt in this example), or namely the TDDB lifetime, can be predicted. The method for providing a reliability assurance according to the present embodiment assures a reliability of a semiconductor device, in the case when the TDDB lifetime thus obtained is equal to or higher than a predetermined standardized value.

Advantageous effects obtainable by employing the configuration of the present embodiment will be described. The TEG 1 is provided with a plurality of unit transistors arranged to form a lattice pattern. This allows providing a reduced area of respective unit transistors, while reducing an increase in the measurement time, although the reduced area of each of the unit transistors decreases a probability of occurring a dielectric breakdown in each of the unit transistors, higher probability of occurring a dielectric breakdown in the entire unit transistors can be maintained. Therefore, this configuration can provide a reduced level of a leakage current generated due to a tunnel effect and flowing through the gate dielectric of respective unit transistors. Thus, the TEG 1, which is capable of providing a prediction of the TDDB lifetime with higher accuracy in shorter time, the method for evaluating electrical characteristics, can be achieved.

Since larger area of the unit transistor provides larger leakage current due to the tunnel effect, the change of the leakage current corresponding to the dielectric breakdown becomes smaller. This will bring the judgment on whether a dielectric breakdown is occurred or not to be in difficulty. In view of such problem, smaller area of the respective unit transistors as described in the present embodiment provides relatively larger leakage current due to the dielectric breakdown, leading to obtaining an advantageous effect of easily obtaining the determination of occurring the dielectric breakdown.

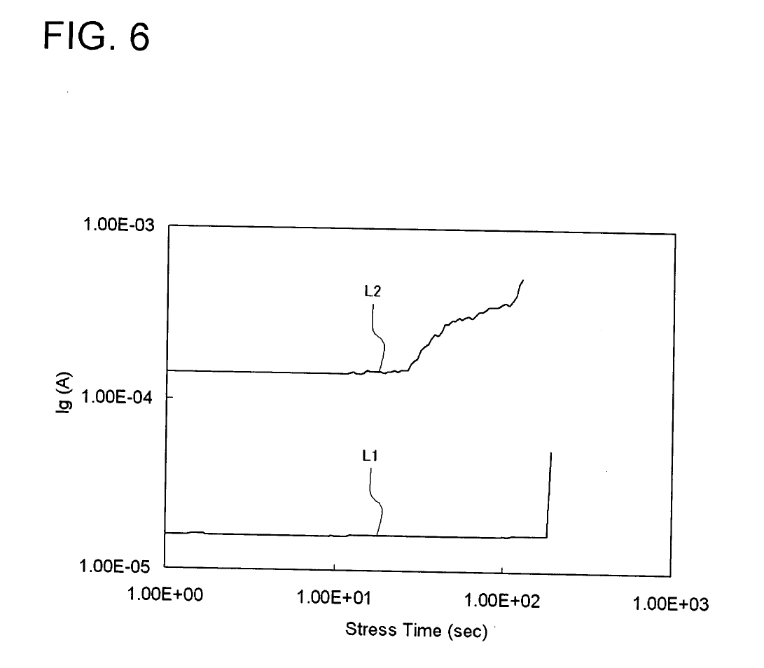

FIG. 6 is graph, showing experimental results performed for confirming such advantageous effect. Abscissa of the graph represents time of applying stress voltage (sec), and ordinate represents gate current (A). Line L1 represents results in a case that a TEG having a plurality of divided unit transistors (gate length: 0.2 μm, gate width: 1 μm) as in the present embodiment, and line L2 represents results in a case that a TEG having one unit transistor (gate length: 2 μm, gate width: 10 μm). More specifically, sum of areas of 100 unit transistors of the former TEG is equivalent to the single unit transistor of the latter TEG. The stress voltage and the measured temperature are 2.5 Volts and 150 degree C., respectively.

As can be seen from the graph, provided that a grand total of area of the unit transistor(s) in the TEG is constant, a change in the waveform resulting from a dielectric breakdown more clearly appears in the case of a plurality of small unit transistors (line L1), as compared with the case of single large unit transistor (line L2). Consequently, according to the configuration of the present embodiment, an occurrence of a dielectric breakdown can be easily detected.

An optimum total area of the unit transistors for detecting the dielectric breakdown depends upon the level of the change in the gate current. When an SiO2 film having a film thickness 10 nm is employed, the sufficient total area of the unit transistors may be 10 μm×10 μm=100 μm2. However, in order to detect a breakdown mode created in an SiO2 thin film having a thickness of equal to or less than 2 nm as shown in FIG. 6, a required gate current change can be detected only by reducing the gate area of the unit transistor to about 0.2 μm2. Appropriate gate area of the unit transistor depends upon the thickness and the type of material (for example, SiO2, SiON, high-k gate dielectric) of the gate dielectric to be evaluated, and since larger gate leakage current per unit area tends to require smaller gate area of the unit transistor, the TEG is preferably configured with the unit transistor having the gate area that is required according to the film thickness and the type of material of the gate dielectric to be evaluated.

In addition, in the TEG 1, a plurality of unit transistors are arranged to form a lattice-shape arrangement or pattern. This allows providing a reduced area of the region where the unit transistors are provided.

In the method for evaluating electrical characteristics according to the present embodiment, the gate current is measured for each of the unit transistors after a stress voltage is applied to the gate dielectric of all unit transistors. Since the leakage current due to the tunnel effect in each of the unit transistors is reduced as described above, an influence of a parasitic resistance is weakened by employing the above-described measuring process, thereby providing an improved accuracy for the measurement.

Accuracy for detecting the breakdown is generally, in inverse proportion to the gate area of a single transistor. In other words, when the accuracy is adjusted by selecting a suitable stress conditions or the like, the required measuring time is in proportion to the gate area of the single transistor. Since the gate area of the single transistor is 1/100 in the evaluation pattern according to the present embodiment show in FIG. 6, the measuring time for achieving the same accuracy can also be reduced to 1/100.

Time required for evaluating the reliability is considerably increased as increasing the level of the integration of the semiconductor devices. Products cannot be launched to the commercial market without obtaining sufficient product reliability. The method for evaluating the TDDB by employing the technique according to the present invention to assure the reliability of the product based on the evaluation data allows considerably reducing the time required for the product development.

Further, in the TEG 1, a short-circuited between the source region and the drain region is created. This allows supplying carrier to the region under the gate dielectric 22 from the source region and the drain region located in the both sides thereof, so that a formation of an inversion layer is facilitated. Since the measurement is performed under the condition that is closer to the real operation of the transistor by performing the measurement under the condition that the inversion layer is formed (hereinafter referred to as “inverted state”), the TDDB lifetime can be measured with higher accuracy.

Since the technology described in Japanese Patent Laid-Open No. 2003-31,632 employs the MOS capacitor as an element to be evaluated, the measurement under the inverted state cannot be performed, and therefore the TDDB lifetime cannot be appropriately predicted. Similarly, Japanese Patent Laid-Open No. H7-66,260 employs the device having the metal-insulator-metal (MIM) structure as the element to be evaluated, the measurement under the inverted state cannot be performed.

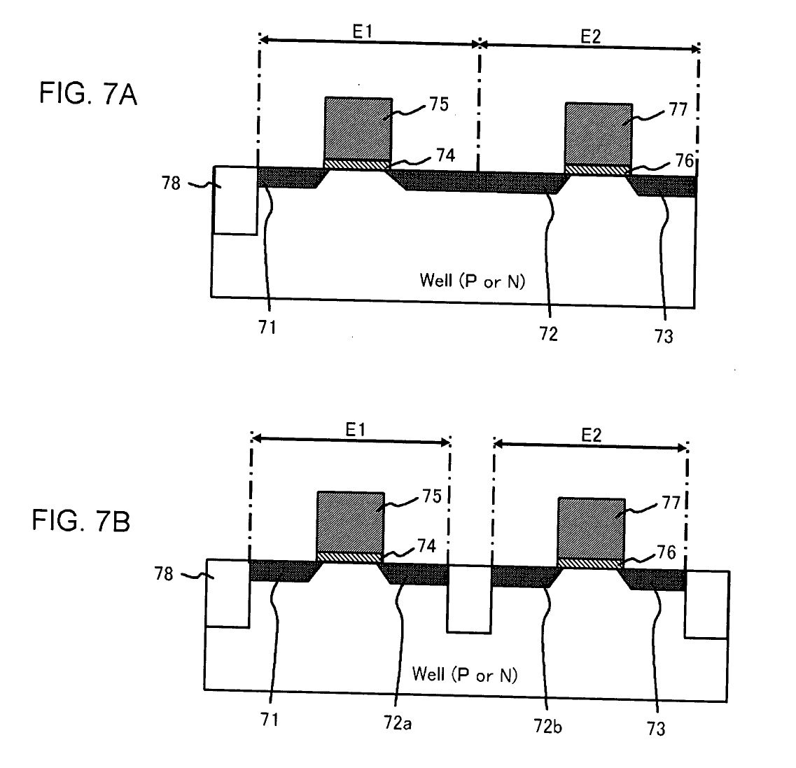

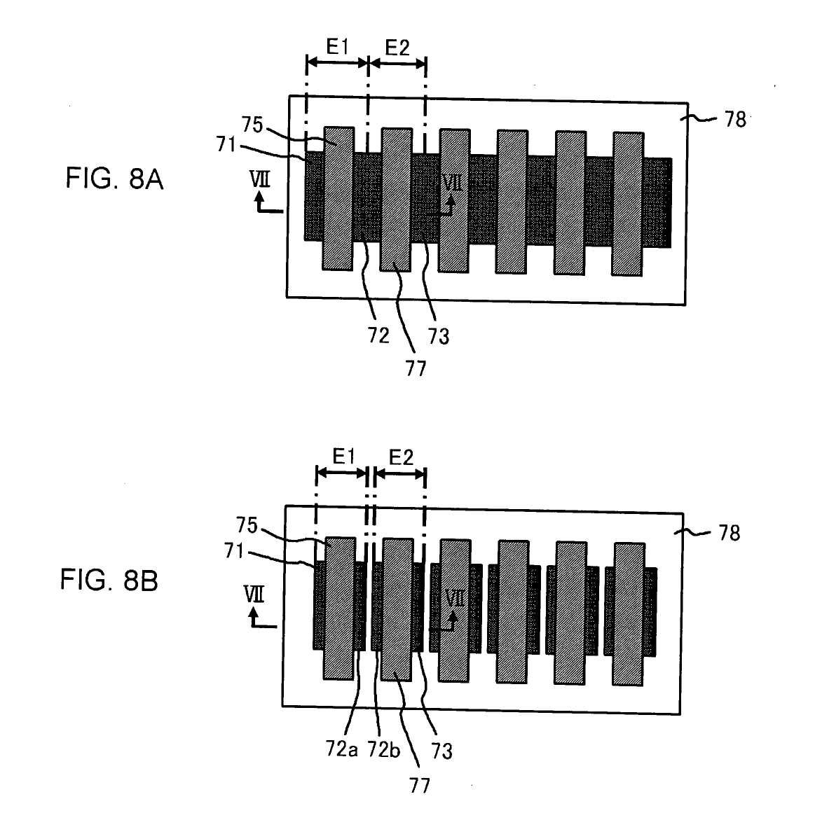

In addition, Japanese Patent Laid-Open No. 2002-50,664 discloses that the transistor structure is adopted for the element to be evaluated. The structure of the TEG described in Japanese Patent Laid-Open No. 2002-50,664 will be described in reference to FIG. 7A and FIG. 8A. FIG. 7A illustrates a cross section along line VII-VII line of FIG. 8A. An element E1 to be evaluated includes a source region 71, a drain region (source-drain region 72), a gate dielectric 74 and a gate electrode 75. An element E2 to be evaluated includes a source region (source-drain region 72), a drain region 73, a gate dielectric 76 and a gate electrode 77. As described above, the Element E1 and the element E2 share the source-drain region 72. However, such structure is theoretically impossible to provide a determination of the occurrence of the dielectric breakdown in each of the elements to be evaluated in the inverted state.

On the contrary, the structure of the TEG of the present embodiment will be described in reference to FIG. 7B and FIG. 8B. FIG. 7B illustrates a cross section along line VII-VII line of FIG. 8B. In these figures, same numeral numbers as employed in FIG. 7A and FIG. 8A are also employed, for the convenience of the description. An element E1 to be evaluated includes a source region 71, a drain region 72a, a gate dielectric 74 and a gate electrode 75. An element E2 to be evaluated includes a source region 72b, a drain region 73, a gate dielectric 76 and a gate electrode 77. The drain region 72a of the element E1 is isolated from the source region 72b of the element E2 by an element isolation region 78. Actually, in the TEG 1 described above, the source region and the drain region of each of the unit transistors are isolated from the source region and the drain region of other unit transistors. According to the structure, an occurrence of a dielectric breakdown in each element to be evaluated can be determined in the inverted state.

It is not intended that the pattern for evaluating electric characteristics, the method for evaluating electrical characteristics, the method for manufacturing the semiconductor device and the method for providing the reliability assurance according to the present invention is limited to the configurations illustrated in the above-described embodiments, and various modifications thereof are available. For example, the example of 3×3 lattice-shaped arrangement has been illustrated as the typical arrangement of the unit transistors in the above-described embodiment. Alternatively, the arrangement of the unit transistors may be m×n lattice-shaped arrangement. In such alternative arrangement, m and n may be arbitrary integer numbers of 2 or more, and may also be the same or different.

The pattern for evaluating electric characteristics and the method for evaluating electric characteristics according to the present invention may be employed in the case of changing the process condition for manufacturing the gate dielectric, or in the case of changing the film thickness of the gate dielectric selected for the product. The conditions for manufacturing the gate dielectric here include, for example, a type of an oxidization process, an oxidizing atmosphere, a process temperature, a process time, a material for the film, a component for the film and the like. Alternatively, once the suitable manufacturing condition and/or the suitable film thickness are determined, the method for evaluating the characteristics of the present invention is applied to such products to measure the TDDB lifetime of the gate dielectric. A standardized value of the TDDB lifetime of the gate dielectric of the transistor for a manufacturing condition and a film thickness applied to a certain product is previously established, and it is determined that a reliability is guaranteed if the measured TDDB lifetime is not lower than the standardized value, and a reliability is not guaranteed if the measured TDDB lifetime is lower than the standardized value. The standardized value of the TDDB lifetime can be established as, for example, ten years. When the pattern for evaluating electric characteristics cannot be mounted a product wafer, a gate dielectric having a film thickness and manufactured under the manufacturing condition, for which the pattern is actually applied to a product, is alternatively applied to manufacture a pseudo workpiece on another wafer, and a pseudo reliability testing of a product is performed to provide a reliability assurance.

The method for evaluating electric characteristics according to the present invention illustrated here includes the description that larger positive stress voltage is applied to the gate electrode and a positive voltage, which is closer to that applied in the operating state, is applied to the gate electrode to monitor the occurrence of the breakdown, if the n-type MOS transistor for example is employed. However, the polarity of voltage is not limited thereto.

The pattern for evaluation according to the present invention may be composed of only n-type transistors or may be composed of only p-type transistors to provide further advantages of the present invention. However, even if both of the n-type and the p-type MOS transistors are employed, only the n-type transistors, for example, are selected to measure the data for determining the reliability can also of course be achieved. Alternatively, if the same stress voltages are applied to the gate electrodes of the n-type and the p-type MOS transistors, a stress of inverted state is applied to the n-type MOS transistor and a stress of accumulated state is applied to the p-type MOS transistor to allow simultaneous measurements of the TDDB lifetime for the n-type and the p-type MOS transistors, respectively.

In the evaluation pattern of the present invention, the most advantageous method of the present invention is to constitute the unit transistors having the substantially same dimension. This is because the sensitivity of detecting the breakdown is in inverse proportion to the gate area. However, even if the unit transistors having different gate areas are employed, the advantageous effect of the present invention is also exhibited.

While the salicide structure is illustrated as the preferable transistor structure in the above-described embodiment, the available transistor structure is not limited thereto, and it is clear that, for example, a metallic gate electrode is also available.

It is apparent that the present invention is not limited to the above embodiment, and may be modified and changed without departing from the scope and spirit of the invention.

What is claimed is:

1. A pattern for evaluating electric characteristics of a transistor, comprising a plurality of unit transistors including a gate dielectric and a source and drain region arranged to form a lattice-shaped arrangement, wherein said source and drain region is mutually short-circuited.

2. The pattern for evaluating electric characteristics of a transistor as set forth in claim 1, wherein said source and drain region of each of said unit transistor is separated from said source and drain region of others of said unit transistors.

3. A method for evaluating electrical characteristics utilizing the pattern for evaluating electric characteristics as set forth in claim 1, comprising:
applying a first voltage to said gate dielectric of said plurality of unit transistors;
measuring a gate current for each of said a plurality of unit transistors when a second voltage is applied to said gate dielectric, after applying said first voltage;
determining a magnitude relation between a level of said gate current and a predetermined reference value; and
deciding that a breakdown is caused, if the level of said gate current exceeds said reference value according to a result in said determining the magnitude relation.

4. The method for evaluating electrical characteristics as set forth in claim 3, wherein, in said applying the first voltage and in said measuring the gate current, said first and said second voltages are applied so as to form an inversion layer in the semiconductor surface under said gate dielectric.

5. The method for evaluating electrical characteristics as set forth in claim 4, wherein each of said unit transistors is an n-channel, and wherein, in said applying the first voltage and in said measuring the gate current, said first and said second voltages are applied so as to provide a potential at the gate electrode that is higher than the potentials at said source and drain region.

6. The method for evaluating electrical characteristics as set forth in claim 4, wherein each of said unit transistors is a p-channel, and wherein, in said applying the first voltage and in said measuring the gate current, said first and said second voltages are applied so as to provide a potential at the gate electrode that is lower than the potentials at said source and drain region.

7. The method for evaluating electrical characteristics as set forth in claim 3, wherein said applying the first voltage, said measuring the gate current, said determining the magnitude relation and said deciding that a breakdown is caused are repeated until it is decided that a breakdown is caused in said deciding that a breakdown is caused.

8. A method for manufacturing a semiconductor device, comprising:
forming a plurality of unit transistors so as to be arranged to form a lattice-shaped pattern, each of said unit transistors having a gate dielectric; and
forming an interconnect so as to short-circuit between a source and drain region of each of said unit transistors.

9. The method for manufacturing the semiconductor device as set forth in claim 8, wherein said plurality of unit transistors are formed on a scribe line of a semiconductor wafer.

10. The method for manufacturing the semiconductor device as set forth in claim 9, further comprising
dicing said semiconductor wafer having said plurality of unit transistors formed therein,
wherein said plurality of unit transistors formed on said scribe line of said semiconductor wafer disappears in said dicing the semiconductor wafer.

11. A method for providing a reliability assurance, comprising:
acquiring a breaking time of said gate dielectric in said pattern for evaluating electric characteristics for said different first voltages according to the method for evaluating electrical characteristics as set forth in claim 3; and
acquiring a TDDB lifetime of said gate dielectric based on said breaking time obtained for said the first voltages,
wherein a reliability assurance of a semiconductor device is provided if said TDDB lifetime is not shorter than a standardized value.
